(19) United States
(12) Patent Application Publication
(10) Pub. No.: US 2011/0102006 A1
(43) Pub. Date: May 5, 2011

(54) CIRCUIT AND METHOD FOR TESTING SEMICONDUCTOR APPARATUS

(75) Inventors: Min Seok CHOI, Ichon-si (KR); Jong Chern LEE, Ichon-si (KR); Sang Jin Byeon, Ichon-si (KR); Young Jun KU, Ichon-si (KR)

(73) Assignee: Hynix Semiconductor Inc., Ichon-si (KR)

(21) Appl. No.: 12/651,066

(22) Filed: Dec. 31, 2009

(30) Foreign Application Priority Data
Oct. 29, 2009 (KR) 10-2009-0103598

(51) Int. Cl. G01R 31/26; G01R 31/3187

(52) U.S. Cl. 324/750.3; 324/762.01

(57) ABSTRACT

A circuit for testing a semiconductor apparatus includes a test voltage applying unit configured to apply a test voltage to a first end of a through-silicon via (TSV) in response to a test mode signal and a detecting unit configured to be connected to a second end of the TSV and detect a current outputted from the second end of the TSV.

### CROSS-REFERENCE TO RELATED APPLICATION

The present application claims priority under 35 U.S.C. §119(a) to Korean Application No. 10-2009-0103598, filed on Oct. 29, 2009, in the Korean Intellectual Property Office, which is incorporated herein by reference in its entirety as if set forth in full.

### BACKGROUND

1. Technical Field

Various embodiments of the present disclosure generally relate to a semiconductor apparatus, and more particularly, to a circuit and a method for testing a semiconductor apparatus.

2. Related Art

In order to increase the integration of a semiconductor apparatus, a three-dimensional (3D) semiconductor apparatus comprising a plurality of stacked chips has been developed. The stacked chips provide a structure that enables the 3D semiconductor apparatus to be packaged in a single package. Recently, a through-silicon via (TSV) type semiconductor apparatus has been developed in which silicon vias are formed to pass through the plurality of stacked chips so that all of the chips are electrically connected to one another.

The 3D semiconductor apparatus has the plurality of TSVs such that the plurality of stacked chips can commonly receive various signals. For example, in the case of a memory apparatus, the plurality of stacked chips can commonly receive address signals, test signals, input/output line signals and command signals through the TSVs.

Various defects, however, may occur in the TSVs. For example, the defects can include voids which are produced due to incomplete filling of a conductive material in the TSVs, bump contact fails which result due to warpage of the chips or migration of a bump material, and cracks of the TSVs themselves.

Since the TSVs electrically connect the plurality of chips, if a TSV creates an open circuit due to an occurrence of a defect, the TSV cannot function properly. Therefore, a defective TSV must be replaced with a functional TSV.

As a result, since proper connection of TSVs is important for reliable product manufacture, there is a need for a method of determining whether TSVs are properly connected.

### SUMMARY OF THE INVENTION

Various aspects of the present invention comprise a circuit and a method for testing a semiconductor apparatus which can determine whether a TSV is connected.

In one aspect of the present invention, a circuit for testing a semiconductor apparatus comprises a test voltage applying unit configured to apply a test voltage to a first end of a through-silicon via (TSV) in response to a test mode signal; and a detecting unit configured to be connected to a second end of the TSV and detect a current outputted from the second end of the TSV.

In another aspect of the present invention, a method of testing a semiconductor apparatus comprising applying a current to a TSV during a testing operation; and comparing an amount of the current flowing through the TSV with a reference value.

In still another aspect of the present invention, a circuit for testing a semiconductor apparatus comprises a test voltage applying unit configured to apply a test voltage to a first end of a TSV in response to a test mode signal; and a detection unit configured to be connected to a second end of the TSV, compare a voltage outputted from the second end of the TSV with a reference voltage, and generate a detection signal.

In still another aspect of the present invention, a circuit for testing a semiconductor apparatus comprises a test voltage applying section configured to apply a test voltage to a plurality of TSVs in response to a test mode signal; and a determining section configured to be sequentially connected to one of the plurality of TSVs in response to the test mode signal.

In still another aspect of the present invention, a circuit for testing a semiconductor apparatus comprises a test voltage applying section configured to apply a test voltage to first and second TSVs in response to a test mode signal; and a determining section configured to be connected to the first and second TSVs in response to the test mode signal.

### BRIEF DESCRIPTION OF THE DRAWINGS

The accompanying drawings, which are incorporated in and constitute a part of this specification, illustrate various embodiments consistent with the invention and, together with the description, serve to explain the principles of the invention. FIGS. 1A and 1B are diagrams schematically illustrating a configuration of a circuit for testing a semiconductor apparatus according to one embodiment of the present invention.

FIG. 2 is a diagram schematically illustrating a configuration of a circuit for testing a semiconductor apparatus according to one embodiment of the present invention.

FIG. 3 is a diagram illustrating the configuration of a determining section of the semiconductor apparatus shown in FIG. 2.

FIG. 4 is a timing diagram showing an operation of the test circuit shown in FIG. 2.

### DETAILED DESCRIPTION OF THE EMBODIMENTS

Advantages and characteristics of the present invention and a method for achieving them will be apparent with reference to embodiments described below with reference to the accompanying drawings. However, the present invention is not limited to the exemplary embodiments described below but may be implemented in various forms. Therefore, the exemplary embodiments are provided to enable those skilled in the art to thoroughly understand the teaching of the present invention and to completely inform the scope of the present invention and the exemplary embodiment is just defined by the scope of the appended claims. Throughout the specification, like elements refer to like reference numerals.

FIGS. 1A and 1B are diagrams schematically illustrating a configuration of a circuit for testing a semiconductor apparatus according to one embodiment of the present invention. Referring to FIGS. 1A and B, a test circuit comprises a test voltage applying unit 10, a through-silicon via (TSV), and a detecting unit 20. The test voltage applying unit 10 applies a test voltage Vtest to the TSV in response to a test mode signal TM. The test mode signal TM comprises a signal that is inputted to test the semiconductor apparatus. When the test mode signal TM is inputted, a testing operation may begin. Accordingly, if the test mode signal TM is enabled and the testing operation is started, the test voltage applying unit 10 applies the test voltage Vtest to the TSV.

The test voltage applying unit 10 may comprise, for example, a metal oxide semiconductor (MOS) transistor. It is to be noted that the test voltage applying unit 10 may comprise a p-type metal oxide semiconductor (PMOS) transistor P1 in FIG. 1A or an n-type metal oxide semiconductor (NMOS) transistor N1 in FIG. 1B. In FIG. 1A, the PMOS transistor P1 has a gate which receives an inverted signal TMb of the test mode signal TM, a source terminal to which the test voltage Vtest is applied, and a drain terminal which is connected to a first end of the TSV. In FIG. 1B, the NMOS transistor N1 has a gate which receives the test mode signal TM, a drain terminal to which the test voltage Vtest is applied, and a source terminal which is connected to the first end of the TSV. Therefore, if the test mode signal TM is enabled to a high level, the test voltage applying unit 10 may apply the test voltage Vtest to the first end of the TSV.

The detecting unit 20 is connected to a second end of the TSV. Since the detecting unit 20 is connected to the second end of the TSV, the detecting unit 20 can detect a current that flows through the TSV or a voltage that is outputted from the second end of the TSV. A pad which is provided with the semiconductor apparatus may be used as the detecting unit 20. Also, the detecting unit 20 may comprise a differential amplifier. In the case where the detecting unit 20 comprises a pad, the pad may receive current that flows through the TSV. An amount of the current that flows through the TSV may be measured by test equipment or through probe detection. Thus, by comparing the amount of current flowing through the TSV and a reference value, a determination may be made regarding whether the TSV is properly connected.

In a case where the detecting unit 20 comprises a differential amplifier, the detecting unit 20 may amplify a difference between the voltage outputted from the second end of the TSV and a reference voltage, and generate a detection signal. Since the test voltage Vtest is applied to the first end of the TSV and if the test mode signal TM is enabled, the detecting unit 20 may compare the voltage outputted from the second end of the TSV with the reference voltage and generate the detection signal. If the level of the voltage outputted from the second end of the TSV is higher than the level of the reference voltage, a determination regarding whether the TSV is properly connected can be determined by the detection signal because the detection signal has been enabled. Because the detection signal has information regarding proper or improper connection or disconnection of the TSV, the detection signal may be used for various purposes in a semiconductor apparatus, such as, for example, for repair.

The reference value and the reference voltage can be changed depending on the level of the test voltage Vtest and a desired level. The test voltage Vtest may comprise, for example, an external voltage. When the test voltage Vtest comprises an external voltage, the reference value and the reference voltage may be appropriately set in consideration of the threshold voltage of the MOS transistor comprising the test voltage applying unit 10 and the conductivity of the TSV. For example, the reference value may be set to one half of a maximum amount of current capable of flowing when the test voltage Vtest is applied, and the reference voltage may be set to one half of the test voltage Vtest.

Below is an exemplary operation of the circuit for testing a semiconductor apparatus in accordance with the embodiment of the present invention. If the test mode signal TM is enabled and the test voltage Vtest is applied to the first end of the TSV, a current flows through the TSV. The detecting unit 20 is applied with the current or voltage outputted from the second end of the TSV. If an amount of current outputted from the second end of the TSV is greater than the reference value, the TSV may be determined as being properly connected, and if the amount of current is less than the reference value, the TSV may be determined as being improperly connected or disconnected. Similarly, if the level of the voltage outputted from the second end of the TSV is higher than the level of the reference voltage so that the detection signal is enabled, the TSV may be determined as being properly connected. Conversely, if the level of the voltage outputted from the second end of the TSV is lower than the level of the reference voltage so that the detection signal is disabled, the TSV may be determined as being improperly connected or disconnected.

Accordingly, in the circuit for testing a semiconductor apparatus in accordance with the embodiment of the present invention, whether the TSV of the semiconductor apparatus is open or short-circuited may be tested in a simple and convenient manner. However, because the semiconductor apparatus comprises a plurality of TSVs, it is difficult and time-consuming to individually check the connections of the TSVs. Therefore, a method for simultaneously testing whether a plurality of TSVs is open or short-circuited is required.

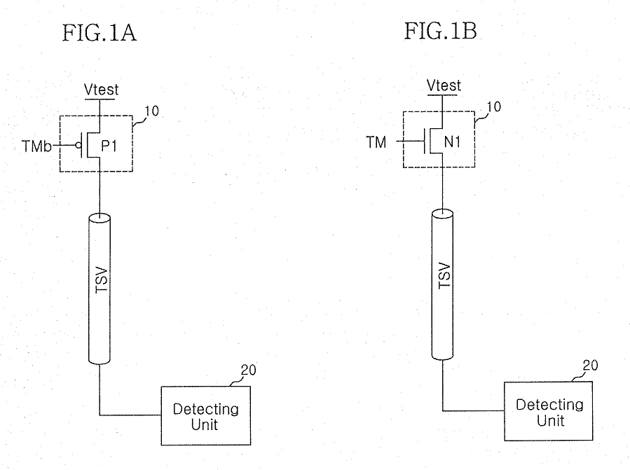

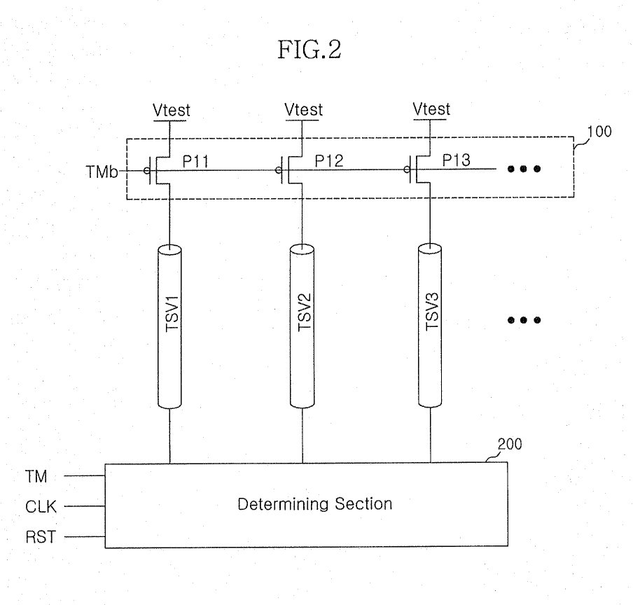

FIG. 2 is a diagram schematically illustrating a configuration of a circuit for testing a semiconductor apparatus in accordance with one embodiment of the present invention. Referring to FIG. 2, a test circuit comprises a test voltage applying section 100, a plurality of TSVs designated by TSV1, TSV2, TSV3 . . . , and a determining section 200.

The test voltage applying section 100 applies a test voltage Vtest to the plurality of respective TSVs TSV1, TSV2, TSV3 . . . , in response to a test mode signal TM. If the test mode signal TM is enabled at a start of a testing operation for a semiconductor apparatus, the test voltage applying section 100 applies the test voltage Vtest to the plurality of respective TSVs TSV1, TSV2, TSV3, . . . , In FIG. 2, the test voltage applying section 100 may comprise PMOS transistors which are respectively connected to first ends of the respective TSVs TSV1, TSV2, TSV3, . . . . Of course, the test voltage applying section 100 may comprise NMOS transistors as shown in FIG. 1.

As shown in FIG. 2, it is to be understood that one of ordinary skill in the art can appreciate that the technical concept of the present invention can be applied in the same way even though the number of TSVs increases. In FIG. 2, the test voltage applying section 100 comprises first through third PMOS transistors P11, P12 and P13. The first PMOS transistor P11 has a gate which receives an inverted signal TMb of the test mode signal TM, a source terminal which receives the test voltage Vtest, and a drain terminal which is connected to the first end of the first TSV TSV1. The second PMOS transistor P12 has a gate which receives the inverted signal TMb of the test mode signal TM, a source terminal which receives the test voltage Vtest, and a drain terminal which is connected to the first end of the second TSV TSV2. The third PMOS transistor P13 has a gate which receives the inverted signal TMb of the test mode signal TM, a source terminal which receives the test voltage Vtest, and a drain terminal which is connected to the first end of the third TSV TSV3.

The determining section 200 may be sequentially connected to respective second ends of the first through third TSVs TSV1, TSV2 and TSV3 for a predetermined interval. When the determining section 200 is connected to the respective first through third TSVs TSV1, TSV2 and TSV3, the determining section 200 detects currents or voltages outputted from the second ends of the first through third TSVs TSV1, TSV2 and TSV3. The predetermined interval may be periodic or random. In FIG. 2, the determining section 200 receives the test mode signal TM, a clock signal CLK and a reset signal RST and detects the currents or voltages outputted through the first through third TSVs TSV1, TSV2 and TSV3. In the embodiment, since the determining section 200 uses the clock signal CLK, the predetermined interval may correspond to, for example, one period of the clock signal CLK.

The determining section 200 may be connected sequentially to one of the first through third TSVs TSV1, TSV2 and TSV3. In other words, intervals during which the determining section 200 is connected to the respective first through third TSVs TSV1, TSV2 and TSV3 do not overlap with one another. Before the testing operation is started, if the reset signal RST is enabled, the determining section 200 is initialized. If the test mode signal TM is enabled, the determining section 200 may be connected to the first TSV TSV1 for one period of the clock signal CLK. The test mode signal TM may then be connected to the second TSV TSV2 for one period of the clock signal CLK, and is thereafter connected to the third TSV TSV3 for one period of the clock signal CLK. Therefore, connections of the determining section 200 with the respective first through third TSVs TSV1, TSV2 and TSV3 do not overlap with one another.

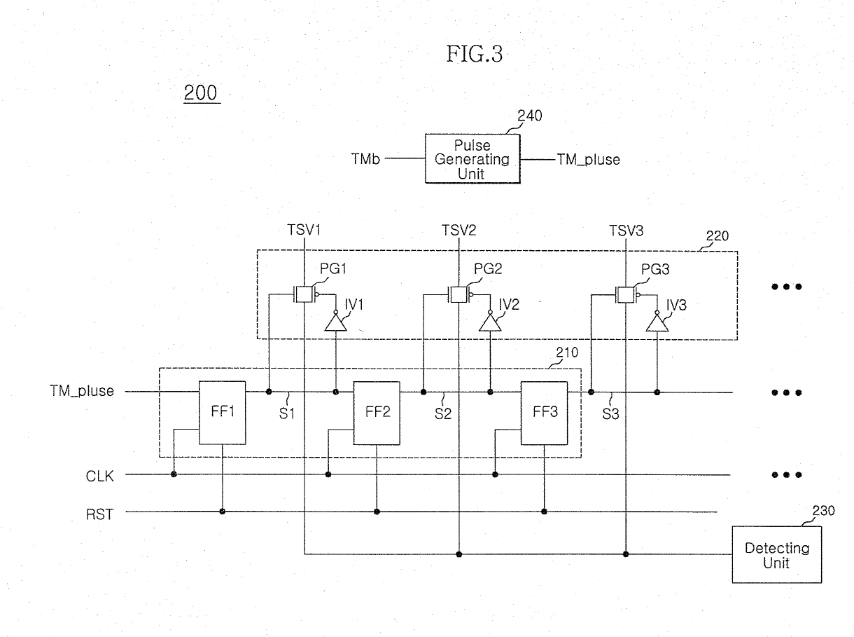

FIG. 3 is a diagram illustrating a configuration of the determining section 200 shown in FIG. 2. Referring to FIG. 3, the determining section 200 comprises a selection signal generating unit 210, a selecting unit 220, and a detecting unit 230. The determining section 200 further comprises a pulse generating unit 240 which is configured to receive the test mode signal TM and generate a test pulse TM_pulse. The pulse generating unit 240 comprises a general pulse generator which can generate the test pulse TM_pulse when the test mode signal TM is enabled.

The selection signal generating unit 210 receives the test pulse TM_pulse, the clock signal CLK and the reset signal RST. The selection signal generating unit 210 is initialized in response to the reset signal RST, and generates first through third selection signals S1, S2 and S3 in response to the test pulse TM_pulse and the clock signal CLK. The selection signal generating unit 210 generates the selection signals S1, S2 and S3 that are sequentially enabled, when the test pulse TM_pulse is inputted.

The selecting unit 220 connects the first through third TSVs TSV1, TSV2 and TSV3 to the detecting unit 230 in response to the selection signals S1, S2 and S3. More specifically, the selecting unit 220 sequentially connects the first through third TSVs TSV1, TSV2 and TSV3 to the detecting unit 230 in response to the selection signals S1, S2 and S3 that are sequentially enabled.

The detecting unit 230 is sequentially connected to the first through third TSVs TSV1, TSV2 and TSV3 by the selecting unit 220. When the detecting unit 230 is connected to the first through third TSVs TSV1, TSV2 and TSV3, the detecting unit 230 detects currents or voltages outputted through the first through third TSVs TSV1, TSV2 and TSV3.

In FIG. 3, the selection signal generating unit 210 comprises first through third flip-flops FF1, FF2 and FF3. The first through third flip-flops FF1, FF2 and FF3 are connected in series and respectively generate the selection signals S1, S2 and S3. The first flip-flop FF1 generates the first selection signal S1 in synchronization with the clock signal CLK when the test pulse TM_pulse is generated. The second flip-flop FF2 receives the first selection signal S1 and generates the second selection signal S2 in synchronization with the clock signal CLK. The third flip-flop FF3 receives the second selection signal S2 and generates the third selection signal S3 in synchronization with the clock signal CLK. Since the second and third flip-flops FF2 and FF3 respectively receive outputs of the first and second flip-flops FF1 and FF2, enabled intervals of the first through third selection signals S1, S2 and S3 do not overlap with one another and may be sequentially defined.

The selecting unit 220 comprises first through third pass gates PG1, PG2 and PG3. The first through third pass gates PG1, PG2 and PG3 are respectively connected to the second ends of the first through third TSVs TSV1, TSV2 and TSV3 and selectively transmit outputs of the second ends of the first through third TSVs. TSV1, TSV2 and TSV3. The first pass gate PG1 connects the second end of the first TSV TSV1 to the detecting unit 230 in response to the first selection signal S1 and an inverted signal of the first selection signal S1 that is inverted by a first inverter IV1. The second pass gate PG2 connects the second end of the second TSV TSV2 to the detecting unit 230 in response to the second selection signal S2 and an inverted signal of the second selection signal S2 that is inverted by a second inverter IV2. The third pass gate PG3 connects the second end of the third TSV TSV3 with the detecting unit 230 in response to the third selection signal S3 and an inverted signal of the third selection signal S3 that is inverted by a third inverter IV3.

The detecting unit 230 may comprise pads or differential amplifiers as shown in FIG. 1. The detecting unit 230 may be constructed in the same manner as the detecting unit 20 of FIG. 1 as described above.

If the determining section 200 is configured as described above, and if the test mode signal TM is enabled, the determining section 200 may be sequentially connected to the first through third TSVs TSV1, TSV2 and TSV3, detect the currents or voltages outputted through the first through third TSVs TSV1, TSV2 and TSV3, and determine at once whether the first through third TSVs are open or short-circuited.

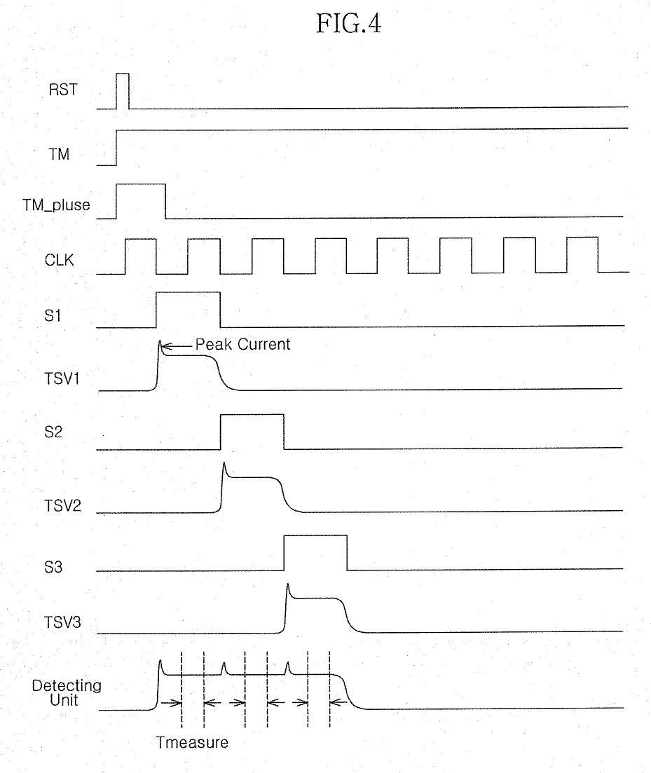

FIG. 4 is a timing diagram showing operations of the test circuit shown in FIG. 2. The operations of the circuit for testing a semiconductor apparatus in accordance with the embodiment of the present invention are described below with reference to FIGS. 2-4.

First, if the reset signal RST is enabled, the determining section 200 is initialized. Thereafter, the test mode signal TM is enabled to start a testing operation for a semiconductor apparatus. If the test mode signal TM is enabled, the test voltage applying section 100 applies the test voltage Vtest to the first through third TSVs TSV1, TSV2 and TSV3.

If the test mode signal TM is enabled, the pulse generating unit 240 generates the test pulse TM_pulse. The first flip-flop FF1 of the selection signal generating section 210 latches the test pulse TM_pulse at the falling edge of the clock signal CLK and outputs the latched signal until the next falling edge of the clock signal CLK. Thus, the first flip-flop FF1 generates the first selection signal S1 that is enabled for one period of the clock signal CLK. Similarly, the second flip-flop FF2 receives the first selection signal S1 and generates the second selection signal S2 that is enabled for one period of the clock signal CLK, and the third flip-flop FF3 receives the second selection signal S2 and generates the third selection signal S3 that is enabled for one period of the clock signal CLK.

The first pass gate PG1 of the selecting unit 220 connects the first TSV TSV1 to the detecting unit 230 in response to the first selection signal S1. Similarly, the second pass gate PG2 of the selecting unit 220 connects the second TSV TSV2 to the detecting unit 230 in response to the second selection signal S2, and the third pass gate PG3 of the selecting unit 220 connects the third TSV TSV3 to the detecting unit 230 in response to the third selection signal S3. As shown in FIG. 4, the outputs of the first through third pass gates PG1, PG2 and PG3 are the currents outputted through the first through third TSVs TSV1, TSV2 and TSV3. Peak currents exist in the waveforms of the currents. Since the TSVs filled with a conductive material serve like capacitors before the pass gates PG1, PG2 and PG3 are turned on, peaks are produced at the moments the pass gates PG1, PG2 and PG3 are turned on.

When connected to the respective first through third TSVs TSV1, TSV2 and TSV3, the detecting unit 230 detects currents having flowed through the first through third TSVs TSV1, TSV2 and TSV3. Detecting intervals are shown in FIG. 4. It is preferred that detection timing be set to when a predetermined time has lapsed after the first selection signal S1 is enabled. As described above, if the first through third TSVs TSV1, TSV2 and TSV3 are connected to the detecting unit 230, peak currents are produced. Therefore, it is desirable to detect an amount of a current flowing through the TSV after the peak current vanishes to determine whether the TSV is properly connected. FIG. 4 shows amounts of currents that are detected by the detecting unit 230. Because the currents flowing through the first through third TSVs TSV1, TSV2 and TSV3 are detected by the detecting unit 230, that is, amounts of currents greater than a reference value, a determination may be made that all of the first through third TSVs TSV1, TSV2 and TSV3 are properly connected. If a detected amount of current is less than the reference value, a determination may be made that the corresponding TSV with the detected amount of current less than the reference value is not properly connected. An improperly connected TSV may then be replaced with a repair TSV.

As is apparent from the above description, in the present invention, whether a plurality of TSVs formed in a semiconductor apparatus are properly connected or not can be simultaneously tested. The test circuit according to one aspect of the present invention can detect a connection or disconnection of the TSVs in a precise and convenient manner. Also, in the present invention, a test time can be shortened and the reliability of the semiconductor apparatus improved.

While certain embodiments have been described above, it will be understood to those skilled in the art that the embodiments described are by way of example only. Accordingly, the circuit and the method for testing a semiconductor apparatus described herein should not be limited based on the described embodiments. Rather, the circuit and the method described herein should only be limited in light of the claims that follow when taken in conjunction with the above description and accompanying drawings.

What is claimed is:

1. A circuit for testing a semiconductor apparatus, comprising:
a test voltage applying unit configured to apply a test voltage to a first end of a through-silicon via (TSV) in response to a test mode signal; and
a detecting unit configured to be connected to a second end of the TSV and detect a current outputted from the second end of the TSV.

2. The circuit according to claim 1, wherein the test voltage applying unit applies the test voltage to the first end of the TSV when the test mode signal is enabled.

3. A method of testing a semiconductor apparatus, comprising:
applying a current to a through-silicon via (TSV) during testing operation; and
comparing an amount of the current flowing through the TSV with a reference value.

4. The method according to claim 3, wherein the reference value is substantially identical to or less than a predetermined amount of current.

5. A circuit for testing a semiconductor apparatus, comprising:
a test voltage applying unit configured to apply a test voltage to a first end of a TSV in response to a test mode signal; and
a detection unit configured to be connected to a second end of the TSV, compare a voltage outputted from the second end of the TSV with a reference voltage, and generate a detection signal.

6. The circuit according to claim 5, wherein the test voltage applying unit applies the test voltage to the TSV when the test mode signal is enabled.

7. A circuit for testing a semiconductor apparatus, comprising:
a test voltage applying section configured to apply a test voltage to a plurality of through-silicon vias (TSVs) in response to a test mode signal; and
a determining section configured to be sequentially connected to one of the plurality of TSVs in response to the test mode signal.

8. The circuit according to claim 7, wherein the test voltage applying section applies the test voltage to the plurality of TSVs when the test mode signal is enabled.

9. The circuit according to claim 7, wherein the determining diction comprises:
a selection signal generating unit configured to generate a plurality of selection signals that are synchronized with a clock signal when the test mode signal is enabled;
a selecting unit configured to receive the plurality of selection signals; and
a detecting unit, and
wherein the selecting unit connects the plurality of TSVs to the detecting unit in response to the plurality of selection signals.

10. The circuit according to claim 9, wherein the selection signal generating unit generates the plurality of selection signals such that enabled intervals of the plurality of selection signals do not overlap with one another.

11. The circuit according to claim 9, wherein the selection signal generating unit comprises a plurality of flip-flops; and
wherein a first flip-flop receives the test mode signal and the clock signal, and each of the plurality of flip-flops remaining receives the clock signal and an output of an immediately previous flip-flop.

12. The circuit according to claim 9, wherein the selecting unit comprises a plurality of pass gates which connect the plurality of TSVs with the detecting unit in response to the plurality of selection signals.

13. The circuit according to claim 9, wherein the detecting unit detects a current outputted from each of the plurality of TSVs after a predetermined time when a corresponding selection signal is enabled.

14. A circuit for testing a semiconductor apparatus, comprising:
to a test voltage applying section configured to apply a test voltage to first and second through-silicon vias (TSVs) in response to a test mode signal; and
a determining section configured to be connected to the first and second TSVs in response to the test mode signal.

15. The circuit according to claim 14, wherein the test voltage applying section applies the test voltage to the first and second TSVs when the test mode signal is enabled.

16. The circuit according to claim 14, wherein intervals, during which the determining section is connected to the respective first and second TSVs, do not overlap with each other.

17. The circuit according to claim 14, wherein the determining section comprises:
a selection signal generating unit configured to generate first and second selection signals that are synchronized with a clock signal when the test mode signal is enabled;
a first selecting unit;
a second selecting unit; and
a detecting unit, and
wherein the first selecting unit connects the first TSV to the detecting unit when the first selection signal is enabled, and the second selecting unit connects the second TSV to the detecting unit when the second selection signal is enabled.

18. The circuit according to claim 17, wherein intervals of the first and second selection signals do not overlap with each other.

19. The circuit according to claim 17, wherein the selection signal generating unit comprises:
a first flip-flop configured to receive the test mode signal and the clock signal and generate the first selection signal; and
a second flip-flop configured to receive the clock signal and the first selection signal and generate the second selection signal.

20. The circuit according to claim 17, wherein the detecting unit detects a current outputted from the first TSV after a predetermined time when the first selection signal is enabled, and detects a current outputted from the second TSV after the predetermined time when the second selection signal is enabled.
